(19) United States
(12) Patent Application Publication
(10) Pub. No.: US 2013/0032200 A1
(43) Pub. Date: Feb. 7, 2013

(54) Connection Slider, Frame and Arrangement for Attaching Photovoltaic Modules or Collector Modules and Method for Attaching Frames

(71) Applicants: Sandy Schnitzer, Feldberger Seenlandschaft (DE); Manuel Dhom, Berlin (DE)

(72) Inventors: Sandy Schnitzer, Feldberger Seenlandschaft (DE); Manuel Dhom, Berlin (DE)

(73) Assignee: MOUNTING SYSTEMS GMBH, Rangsdorf (DE)

(21) Appl. No.: 13/634,120

(22) PCT Filed: Mar. 14, 2011
(86) PCT No.: PCT/EP2011/053815

§ 371 Date: Oct. 10, 2012

(30) Foreign Application Priority Data
Mar. 12, 2010 (DE) 10 2010 002 834.7

(51) Int. Cl. H01L 31/048; B23P 11/00; H05K 13/04; F16B 7/20

(52) U.S. Cl. 136/251; 403/188; 29/525.01; 29/592.1; 211/41.1

(57) ABSTRACT

The invention relates to a connection slider for attaching two adjacent frames of photovoltaic modules or collector modules on a profile rail, the connection slider comprising: a main element; two mandrels which extend from two surfaces of the main element oriented in opposite directions, wherein one respective mandrel is insertable into one of the adjacent frames; and a transversal element protruding from the main element, wherein the transversal element has an opposite profile adapted to a profile of the profile rail for providing a form locking connection with the profile rail.

The invention relates to a connection slider for attaching two frames with photovoltaic modules or collector modules on a profile rail, a frame for receiving one or plural photovoltaic modules or collector modules, an arrangement for receiving photovoltaic modules or collector modules, a module field with photovoltaic modules or collector modules, a use of connection sliders for attaching frames and a method for attaching the frames.

Photovoltaic modules or collector modules are typically grouped into module fields and attached in a roof assembly or in a ground assembly on profile rails arranged parallel to one another.

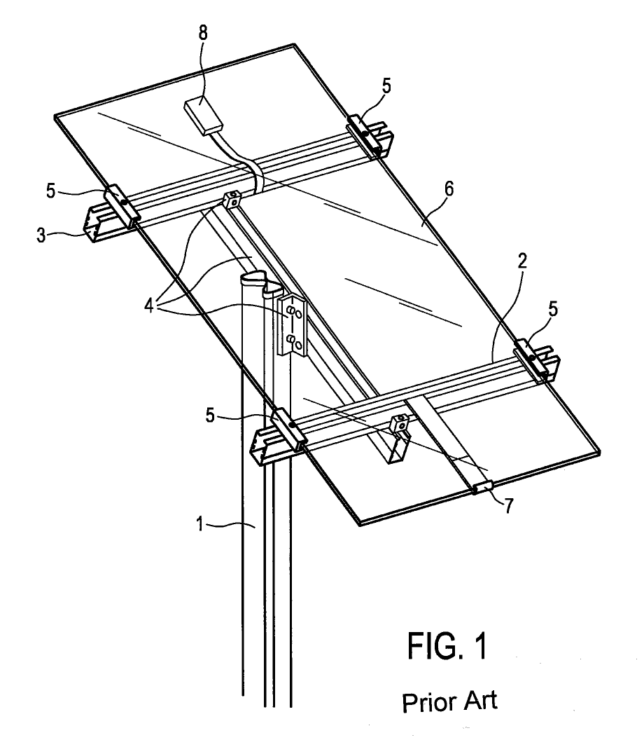

A known arrangement for attaching photovoltaic modules is illustrated in FIG. 1. The arrangement includes a ramming post 1 which is used for anchoring the arrangement in the ground, two profile rails 2, 3 which are connected through an attachment arrangement 4 with the ramming post 1 so that they are arranged parallel to and with an offset from one another, four module supports 5 which are used for lateral attachment of a photovoltaic module 6, a sliding safety 7 which prevents the photovoltaic module from sliding downward out of its position and an electrical connection 8 which is used for running out the electrical power generated by the photovoltaic module.

The illustrated arrangement facilitates constructing module fields with plural photovoltaic modules 6 arranged adjacent to one another on the accordingly longer profile rails 2, 3. Thus the module supports 5 are configured so that they can respectively support two adjacent modules simultaneously. Along the profile rails this way rows of photovoltaic modules can be configured. Furthermore, a plurality of rows of photovoltaic modules can be arranged behind one another on respective ramming posts of their own.

Thus there is a need in the art to attach photovoltaic modules or collector modules in a simpler manner.

According to a first aspect of the invention, this is achieved through a method that includes the following steps:
inserting a first connection slider into a longitudinal groove of a first profile rail;
providing a form locking connection of the first connection slider with the first profile rail;
moving the first connection slider along the longitudinal groove of the first profile rail towards a first frame for inserting a first mandrel of the first connection slider into a recess of the first frame for producing a form locking connection between the first frame and the first connection slider;
inserting a second connection slider into a longitudinal groove of a second profile rail;
establishing a form locking connection of the second connection slider with the second profile rail;
moving the second connection slider along the longitudinal groove of the second profile rail towards the first frame for inserting a first mandrel of the second connection slider into a recess of the first frame for providing a form locking connection between the first frame and the second connection slider;
arranging a second frame on the profile rails adjacent to the first frame, so that, two respective recesses are arranged opposite to one another approximately at identical elevations in the adjacently arranged frame; and
moving the second frame for inserting a respective second mandrel of the connection sliders into the respective recess of the second frame.

Advantageous connection sliders are defined in the second aspect of the invention. Advantageous frames are defined in the third aspect of the invention.

The method according to the first aspect of the invention facilitates a simple assembly of frames which receive photovoltaic modules or collector modules. The applicability of the method, however, is not limited to frames for such modules.

The two connection sliders are inserted through the longitudinal grooves of the two profile rails and provide in an advantageous embodiment for example after a rotation by 90 degrees, a form locking connection with the respective profile rails. Unintentional removing of the connection slider from the profile rail is thus prevented. In the recited embodiment, a removal requires a rotation by another 90°.

Subsequently, the connection sliders are moved along the longitudinal groove of the respective profile rails in order to slide the mandrels of the connection sliders into respectively provided recesses of the frames. After these simple process steps which can be performed without particular force application and without tools, the frame is already connected in a form locking manner with the connection sliders which in turn are connected in a form locking manner with the profile rails. Thus the frame is supported on the profile rails.

For a subsequently performed mounting of the second frame, it is initially arranged on the two profile rails, so that its recesses are arranged approximately at the same level of the recesses of the first frame and thus also relative to the mandrels of the connection sliders. Subsequently, a simple movement of the second frame on the profile rails in a direction towards the first frame suffices, wherein the mandrels of the connection sliders which are not inserted into the recesses of the first frame are inserted into respective recesses of the second frame. Thus the second frame is supported on the profile rails like the first frame.

When the second frame is moved in a direction of the first frame far enough so that the frames and the connection sliders arranged there between are directly adjacent to one another, this means further movement is not possible, the connection sliders are thus also secured against a sliding in a direction of the longitudinal groove. This is performed without the connection sliders having to be bolted together with the profile rail or having to be connected therewith in another complex manner. A bolted connection at an end of a row of frames that is described infra is sufficient.

Besides the described simplicity, the method has the advantage that it can be performed in the advantageous embodiments with a plurality of frames arranged one after another so that two respective adjacent frames are offset from one another through connection sliders arranged there between and so that each frame is supported by four mandrels which are respectively associated with one of the four adjacent connection sliders. After assembly of any number of frames with the associated connection sliders suitably configured end supports can be attached so that a force is imparted upon the frames that is oriented along the profile rails. Thus the frames and also the connection sliders arranged between the frames are supported in position along the longitudinal grooves. Preferably the end supports are bolted together with the profile rails so that they are secured against sliding along the profile rails through friction locking.

Besides the frames, only the connection sliders are required for mounting rows of frames which keeps the amount of mounting material required very small. Furthermore, the described process steps can be performed with the connection sliders quickly without tools and also without significant force application.

It is appreciated that deviations from the method recited supra are possible. For example, the second frame can be arranged on the profile rails before the connection sliders are inserted into the longitudinal grooves of the profile rails. Alternatively, also only one connection slider can be inserted into a longitudinal groove before the second frame is applied. By the same token it is possible to initially insert one or both connection sliders into the longitudinal grooves and to subsequently arrange the second frame, to then insert the first mandrels of the connection sliders into the recesses of the first frame and to subsequently move the second frame so that the second mandrels of the connection sliders are inserted into the recesses of the second frame.

Preferably the method according to the first aspect of the invention is repeated until a desired plurality of frames is mounted adjacent to one another. Typically seven to fifteen, particularly preferably eleven frames arranged adjacent to one another are mounted. Thereafter at least one end support and at least one expansion joint are mounted. While the end support is configured to secure the modules as described supra against sliding in a direction of the profile rails, the expansion joint provides a compensation for length changes which occur due to temperature variations. The end support can be attached for example in a conventional manner through bolting at the profile rails. Thus it has become apparent that arranging an expansion joint after seven to fifteen, in particular eleven modules is particularly advantageous due to the thermal expansion properties of aluminum when this material is being used. Aluminum is advantageous due to its good workability, its low weight and its corrosion resistance.

In a particular preferred embodiment, profile rails are being used that are mounted horizontally, thus parallel to an assembly base, wherein the frames are mounted adjacent to one another on the profile rails. Alternatively, the two profile rails can be arranged at any angle relative to the base, for example the profile rails can be arranged inclined at an acute angle relative to horizontal. The method according to the first aspect of the invention can be used independently from the position of the profile rails. It is only important that the profile rails are parallel to one another.

In a particularly preferred embodiment of the invention, an electrical connection of photovoltaic modules received in the frame is performed according to the method after an assembly of a total of eighteen to twenty six frames, particularly preferably twenty two frames. Connecting this number of photovoltaic modules is advantageous due to the electrical properties of the photovoltaic modules and of the invertors.

A second aspect of the invention relates to a connection slider for attaching two adjacent frames of photovoltaic modules or collector modules on a profile rail, the connection slider including the following:
a main element;
two mandrels which extend from two surfaces of the main element oriented in opposite directions, wherein one respective mandrels is insertable into one of the adjacent frames; and
a transversal element protruding from the main element, wherein the transversal element has an opposite profile adapted to a profile of the profile rail for establishing a form locking connection with the profile rail.

Frames which are attachable with the connection slider according to the second aspect of the invention are described in the third aspect of the invention.

The connection slider according to the second aspect of the invention is a component that can be produced in a simple manner. It facilitates attaching two adjacent frames with photovoltaic modules on a profile rail in a simple manner without requiring tools or particular force application. Preferably the connection slider according to the second aspect of the invention is used in a method according to the first aspect of the invention.

The main element of the connection slider is advantageously configured cuboid. This facilitates a surface contact with the two adjacent frames. Alternatively the main element can also be configured cylindrical or with another shape which facilitates attaching both mandrels and also the transversal component.

The mandrels are configured so that they are insertable into the recesses of frames. The insertion can be implemented in various ways. On the one hand side the mandrel can be moved towards a stationary frame. Alternatively the frame can also be moved towards the stationary mandrel. Eventually the mandrel and also the frame can be moved towards one another. Thus when it is recited in the present embodiment that the mandrel is being moved, this movement can certainly also be implemented by a respective movement of the frame or a movement of the frame and also of the mandrel.

When a mandrel is to be inserted into a recess that is only insignificantly larger, it is apparent that this works best when the mandrel is oriented parallel to its movement direction. In practical applications, however, tilting of the mandrel relative to its ideal direction can occur when mandrels are inserted into a recess. The mandrels of the connection slider are therefore preferably configured tapered proximal to an end protruding from the main element. Thus the tolerance range in which the mandrel can be tilted from an ideal position can be increased, since the tapered end also fits into the recess in this case. Since the thickness of the mandrel increases in a direction from its protruding end to the main element, a form locking connection between the connection slider and the element included in the recess can still be established.

The two mandrels protrude from two surfaces of the main element protruding in opposite direction, wherein the mandrels are preferably both arrange along a common straight line. This straight line is further preferably arranged perpendicular to a symmetry axis of the main element. In this embodiment, both mandrels of a connection slider can be inserted along precisely defined directions into respective recesses of adjacent frames. This facilitates particular simple assembly since only movements along a straight line are necessary.

Alternatively, the mandrels however can be oriented in directions which are not in a straight line which can generate for example an additional retaining effect through wedging after insertion of the mandrels into recesses of adjacent frames.

The transversal element protruding from the main element is used for establishing a form locking connection with the profile rail. For this purpose it has an opposite profile which is adapted to the profile of the profile rail. The transversal element is preferably attached to the main element offset from the mandrels, so that the main element can protrude from the profile rail with a portion where the mandrels are attached, while it can be disposed within the profile rail with the portion where the transversal element is attached.

A longitudinal orientation of the main element is transversal to a longitudinal orientation of the mandrels in a preferred embodiment.

The transversal element can protrude in this embodiment or independently therefrom in two opposite directions from the main element, wherein the two opposite directions are transversal to the longitudinal direction of the main element.

According to a preferred embodiment, the main element and the transversal element viewed in combination have approximately T-shape. The transversal bar of the T is thus the transversal element which includes the opposite profile. Through the T-shape it is facilitated that a form locking connection with the profile rail is established on two pages of the main element. This facilitates a better connection between the connection slider and the profile rail which is in particular stiffened against pivoting.

In another preferred embodiment, the transversal element has two free legs which are respectively wedge shaped and which are attached at surfaces of the main element which are oriented in opposite directions. The wedge tapers viewed in longitudinal direction of the main element with increasing distance from the longitudinal end of the main element. The wedge shape has the advantage that it configures a simple and universally fitting opposite profile. Furthermore, a good fit at suitably configured interior cavities of the profile rails is facilitated through the wider sections of the wedges which are arranged at the ends protruding from the main element.

According to a preferred embodiment, the transversal element of the connection slider is configured so that it is insertable into an opening of the profile of the profile rail and provides a form locking connection with the profile of the profile rail through subsequent rotation by approximately 90 degrees. This facilitates particularly simple arrangement of the connection slider at the profile rail. Thus it is possible to insert the connection sliders at any location of the profile rail, this means it is not necessary to insert the connection sliders at the ends of the profile rail. For insertion, the transversal element is arranged so that it fits through the recited opening of the profile with its largest extension. After the transversal element is inserted through the opening it can be brought into engagement with the profile rail simply by rotating by approximately 90 degrees. Moving the connection slider along the profile rail is still possible, since the profile rail has a constant cross-section in this direction. By the same token, a connection slider which has a mandrel that is already inserted into the frame can be moved away from the frame again in order to disengage the frame. This can be required for example when the frame with its photovoltaic modules or collector modules has to be replaced or maintenance has to be performed at the frame.

When the connection slider is rotated by another 90 degrees from a form locking connection with the profile rail, the connection slider can be removed from the profile rail again without having to be moved to the end of the profile rail.

Particular connection sliders can thus also be removed or replaced without having to disassemble a plurality of adjacent frames and associated attachments.

Preferably the transversal element extends from the main element in two opposite directions which are oriented transversal to a longitudinal direction of the mandrels. When the transversal element is inserted into the opening of the profile rail, the mandrels are initially oriented transversal to the profile rail and are therefore not yet configured to be inserted into the recesses of adjacent frames which contact the profile rail. As recited supra, the connection slider however can be rotated by 90 degrees so that the transversal element provides a form locking connection with the profile rail. Since the mandrels can thus also be rotated by 90°, they are substantially oriented parallel to the profile rail after the rotation. Thus the mandrels are then also oriented in a suitable manner in order to be inserted into respective recesses of adjacent frames that contact the profile rail. Thus, this embodiment provides that after a simple 90 degree rotation, the transversal element and also the two mandrels are oriented in the respective directions in which they are also required for the attachment of the frames at the profile rail.

Preferably, the connection slider is integrally configured in one piece which facilitates simple manufacture, for example through injection molding and a high strength of the connection slider.

Alternatively, however, the connection slider can also be configured from several components, thus e.g. the main element, the mandrels and the transversal element can be respectively produced by themselves and can be connected through threading, welding, gluing or other connection techniques with the connection slider.

In a preferred embodiment of the connection slider, the two mandrels respectively include an electrically conductive contact portion in their longitudinal sections proximal to the main element. The contact portion is configured for providing an electrically conductive contact between the connection slider and a frame in which the connection slider is insertable. A contact portion of this type is preferably an electrically conductive portion of the mandrel, whose diameter is selected precisely fitting to the recess in the frame so that a contact with an inner surface of the recess can be provided when being inserted into the recess. When the recess is shaped as a slotted hole, it certainly suffices that the mandrels are precisely configured transversally to the longitudinal direction of the slotted hole. This way an electrically conductive contact of the frame with the profile rail can be provided through the connection slider for grounding purposes.

The contact portion can have a coarse outer surface, for example a riffle. Thus the profile rail is electrically connectable with the frame in a more reliable manner. This is particularly advantageous when the frame is coated at its outer surfaces with non-conductive material and thus no electrical contact between the frame and the profile rail is generated through the contact of the frame on the profile rail alone.

The length of the mandrel is 1 to 5 cm in various embodiments, preferably 2 to 4 cm, and particularly preferably 2.5 to 3.5 cm. The diameter of the mandrels is for example 6 to 10 mm, preferably 7 to 9 mm, particular preferably 8 mm.

A third aspect relates to a frame for receiving one or plural photovoltaic or collector modules with two frame elements on outsides of the frame that are oriented in opposite directions, wherein the frame elements respectively include two recesses for receiving a respective mandrel of a connection element according to the second aspect of the invention. When the frame is rectangular, the two frame elements are arranged at opposite sides of the rectangle.

The frame facilitates a particularly simple assembly of photovoltaic modules or collector modules on two profiles rails arranged respectively parallel to one another using connection sliders according to the second aspect of the invention. The advantages already described in conjunction with the connection sliders apply in particular when frames according to the third aspect of the invention are used together with connection sliders according to the second aspect of the invention for mounting photovoltaic modules or collector modules. With respect to the advantages, reference is made to the statements provided supra.

Preferably the recesses of the frame are configured as slotted holes. This facilitates easy assembly on the one hand side since a greater clearance is provided when inserting the mandrels of the connection sliders. On the other hand side, the slotted holes provide a tolerance against heat expansion. Since the slotted holes facilitate a particular clearance of the mandrels, a heat expansion of the frame does not lead to wedging with the connection sliders or the profile rails on which the frames are supported.

Preferably the slotted holes have lengths of at least 1.5 cm, particularly preferably at least 2 cm. This facilitates assembly and provides sufficient tolerance against thermal expansion.

It is appreciated that the frame is herein as a component that is independent from the photovoltaic modules or the collector modules, wherein the frame can also be sold without the modules being installed. However, it is appreciated that the frame can also be sold together with the photovoltaic modules or the collector modules. This embodiment is also within the scope of the invention.

According to a fourth aspect, the invention relates to an arrangement including
at least two profile rails arranged parallel to one another;
at least two frames arranged parallel to one another according to the third aspect of the invention, wherein the frames contact the profile rails, wherein;
the frames are arranged on the profile rails, so that at the level of the profile rails, two respective recesses in the frame elements are arranged opposite from and oriented towards one another,
wherein a respective connection slider, according to a second aspect of the invention is arranged between the two recesses oriented opposite to one another, wherein mandrels of the connection slider are inserted into the recesses and wherein the transversal elements of the connection slider are in form locking connection with the respective profile rail and wherein a longitudinal orientation of the mandrels is parallel to a longitudinal orientation of the profile rails.

The arrangement according to the fourth aspect of the invention is advantageously used for supporting photovoltaic modules or collector modules which are received in the frames. They are assembled using connection sliders according to the second aspect of the invention and frames according to the third aspect of the invention and therefore provides all advantages described supra. In particular, mounting is possible with little mounting material, without tools and without particular force application when applying and inserting the connection sliders. Furthermore, particular frames with their photovoltaic modules or collector modules or particular connection sliders can be replaced or removed in a simple manner without requiring disengaging a plurality of bolted connections or removing additional components.

Advantageously, the profile rails of the arrangement are arranged according to the fourth aspect of the invention at different levels above ground. This facilitates placing the frames at a slant angle and thus also placing the photovoltaic modules or collector modules received in the frame at a slant angle which corresponds to a typical assembly of photovoltaic modules or collector modules. The amount of slant angle is thus defined by the elevation difference of the two profile rails and typically adapted to the geographic latitude of the installation location.

Preferably, in the arrangement according to the fourth aspect of the invention, between seven and fifteen, particular preferably eleven frames are arranged adjacent to one another, wherein two respective adjacent frames are only offset from one another through the connection sliders and wherein an end support and an expansion joint are arranged at least at one end of a row thus formed. As already recited in the description of the method according to the first aspect of the invention, an embodiment of this type provides advantageous resistance relative to thermally induced length changes when using the preferred material aluminum. The bolted down end support provides protection against a sliding of frames and connection sliders and is preferably provided with a theft safety. When frames or connection sliders are to be removed or replaced, it suffices to disengage the end support and to move the frames in order to free the element to be removed.

When frames are being used for the arrangement according to the fourth aspect of the invention which frames have slotted holes, this facilitates a tolerance relative to thermally induced expansion transversal to the profile rails as already described supra. Thus the mandrels of the connection sliders and the slotted holes of the frames are preferably configured so that they configure a precisely fitting connection in a direction transversal to the frame surface.

According to a fifth aspect, the invention relates to a module field with photovoltaic modules or collector modules which are mounted through at least one arrangement according to the fourth aspect of the invention.

The advantages of a module field of this type are directly derived from the advantages of the arrangement according to the fourth aspect of the invention. Accordingly, reference is made to the statements provided therein.

Preferably, in a module field with photovoltaic modules according to the fifth aspect of the invention, the photovoltaic modules of 18 to 26 frames, particularly preferably of 22 frames are electrically connected which provides a particularly good adaptation of the power values of photovoltaic modules to inventors.

Furthermore, particularly preferably some of the frames are mounted by at least one arrangement according to the fourth aspect of the invention so that respectively seven to fifteen frames are arranged adjacent to one another and held together by bolted end supports. An expansion joint can be respectively provided adjacent to a row of this type as also described supra.

According to a sixth aspect, the invention relates to using connection sliders according to the second aspect of the invention for attaching at least two frames according to the third aspect of the invention at least two profile rails that are arranged parallel to one another.

The advantages of combined use of these components were already described in detail during their description.

Other features and advantages of the invention are apparent from the detailed descriptions of the embodiments with reference to the subsequent drawing figures, wherein:

FIG. 1 illustrates a prior art device for mounting photovoltaic modules;

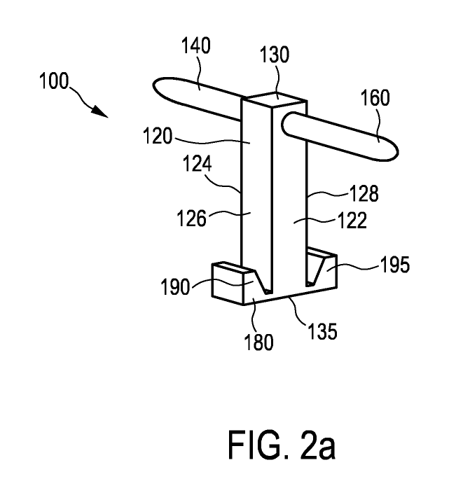

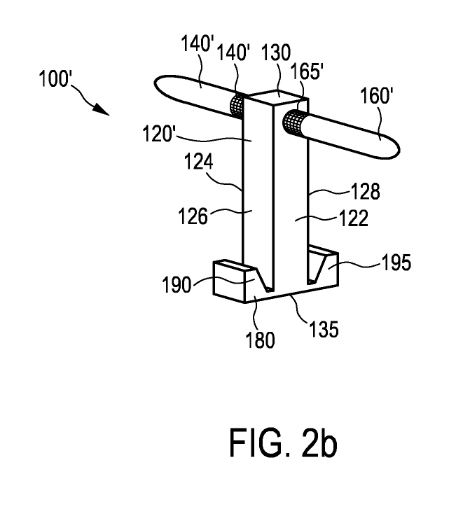

FIG. 2a illustrates a connection slider according to the second aspect of the invention;

FIG. 2b illustrates a modified connection slider according to the second aspect of the invention in which a respective riffled portion is configured at the mandrels;

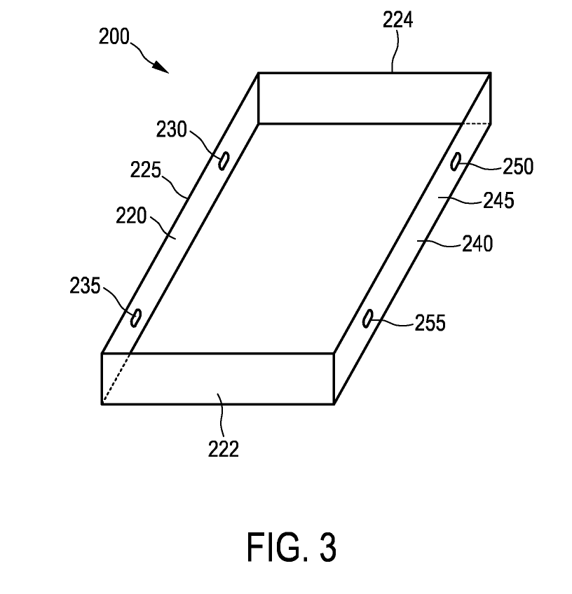

FIG. 3 illustrates a frame for receiving photovoltaic modules or collector modules according to the third aspect of the invention;

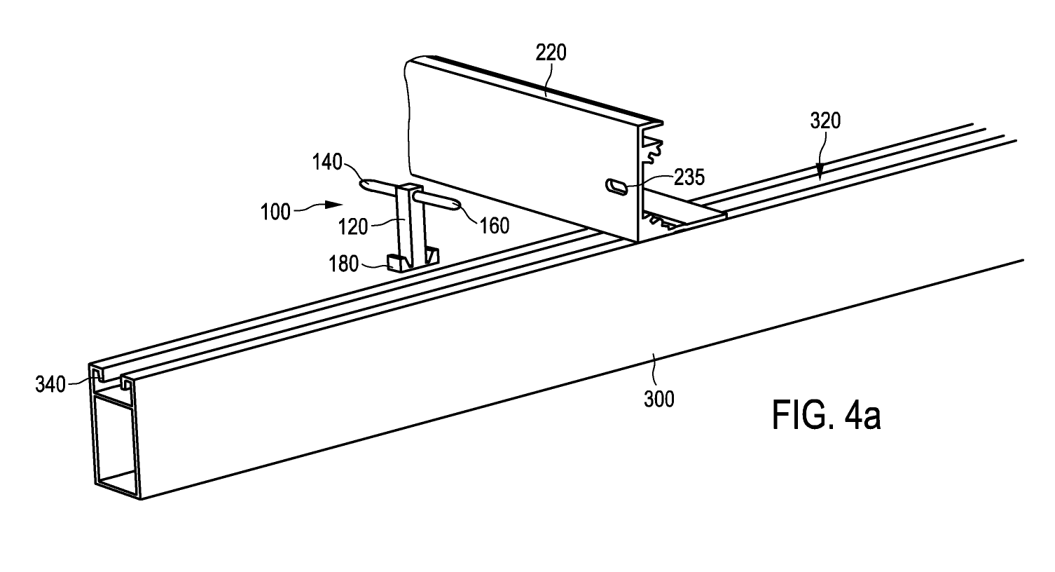

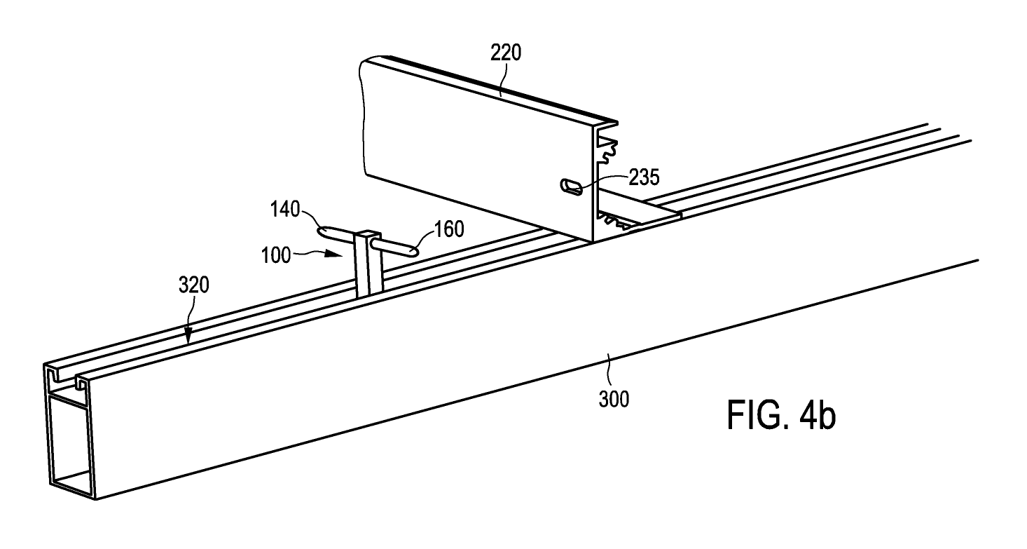

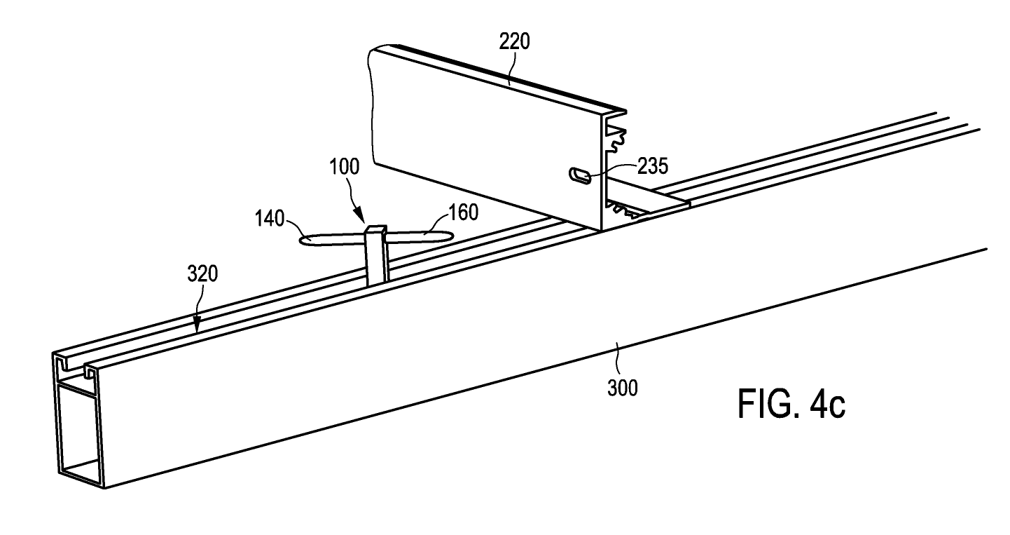

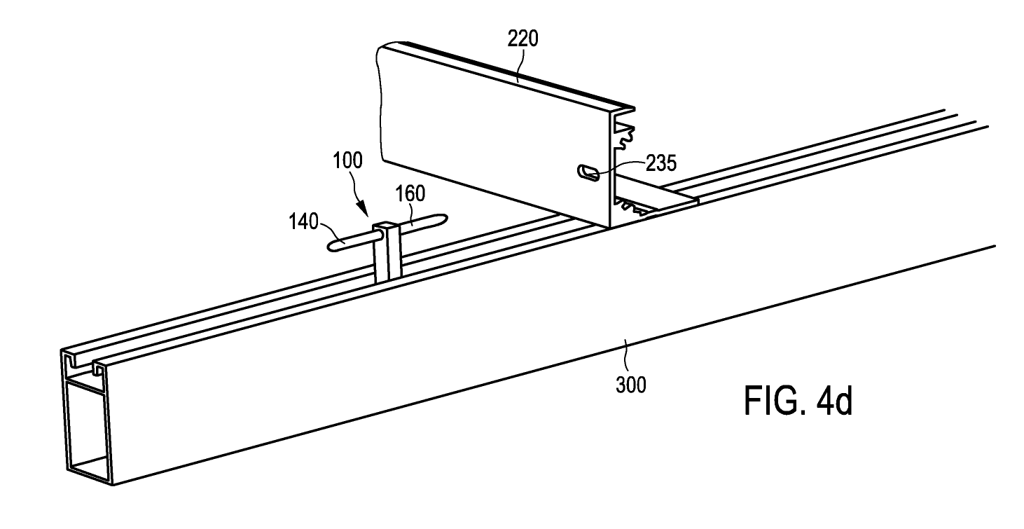

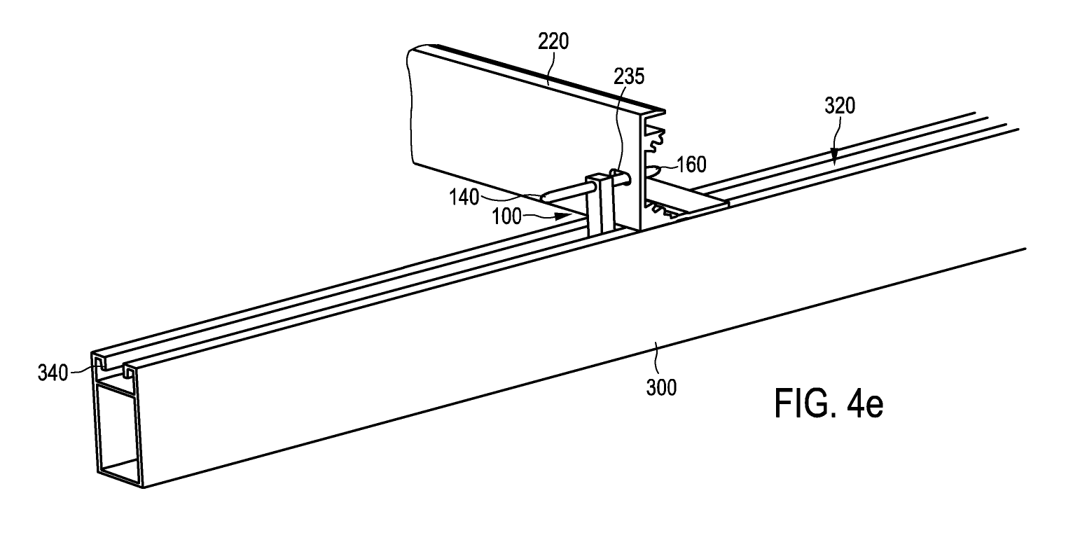

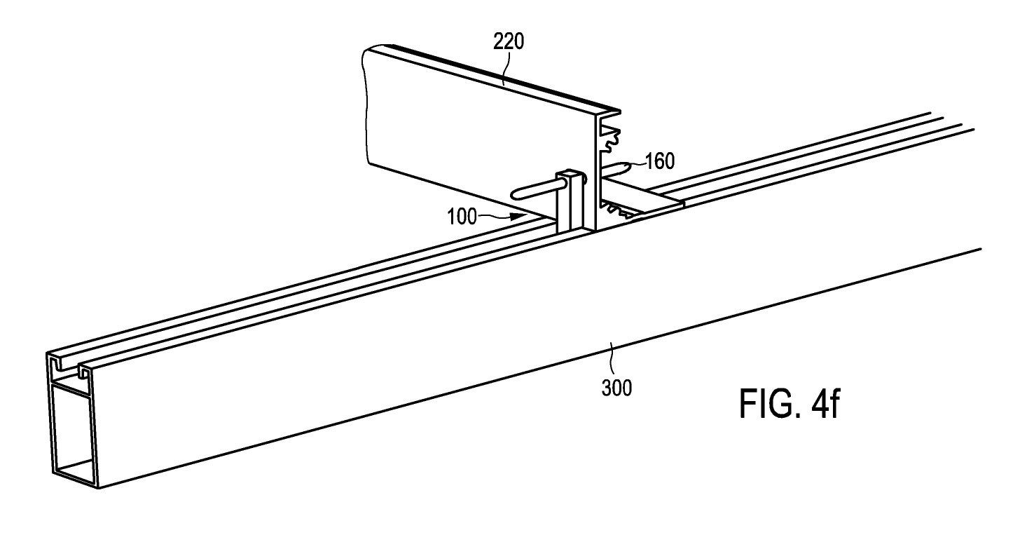

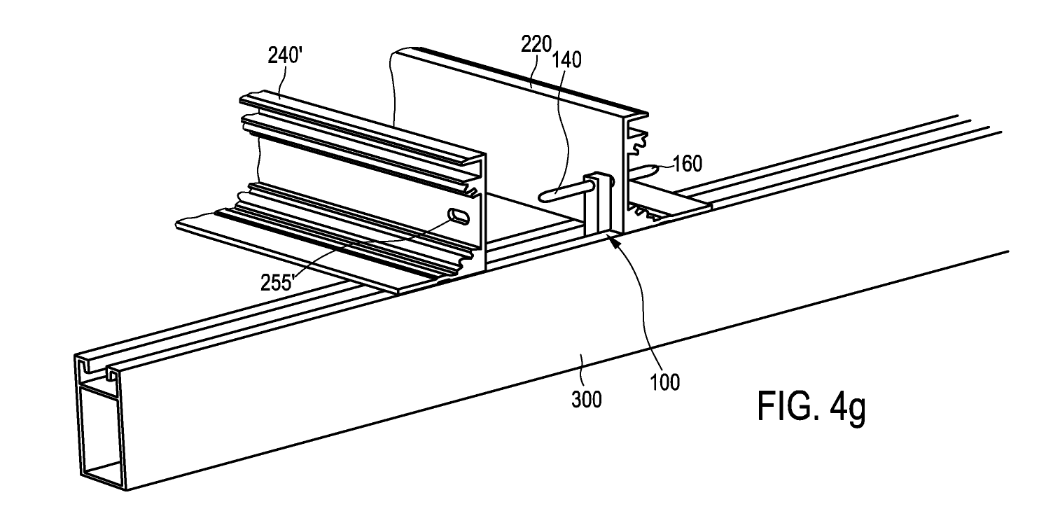

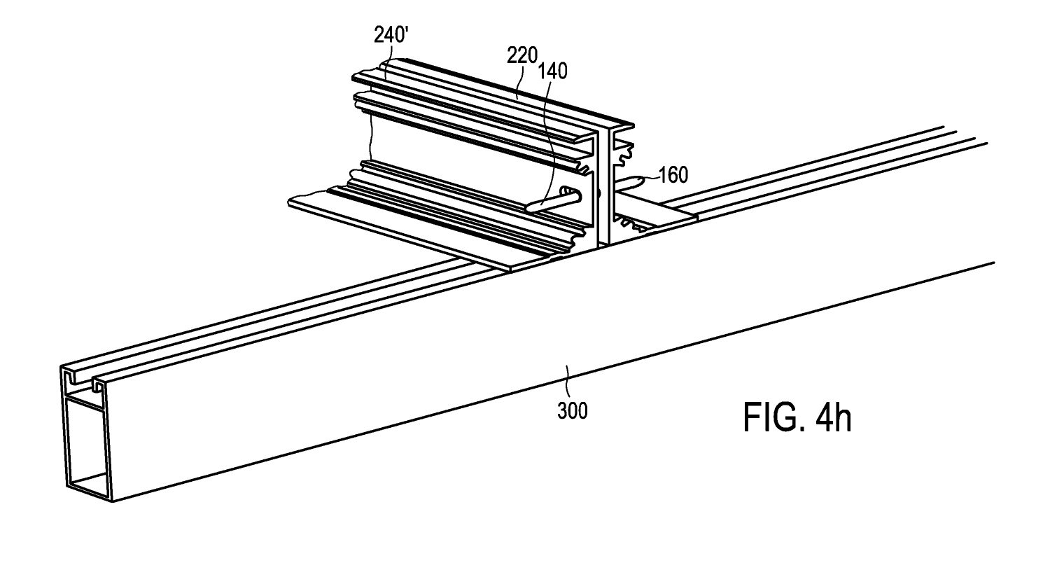

FIGS. 4a to 4h illustrate a method for mounting frames according to the first aspect of the invention;

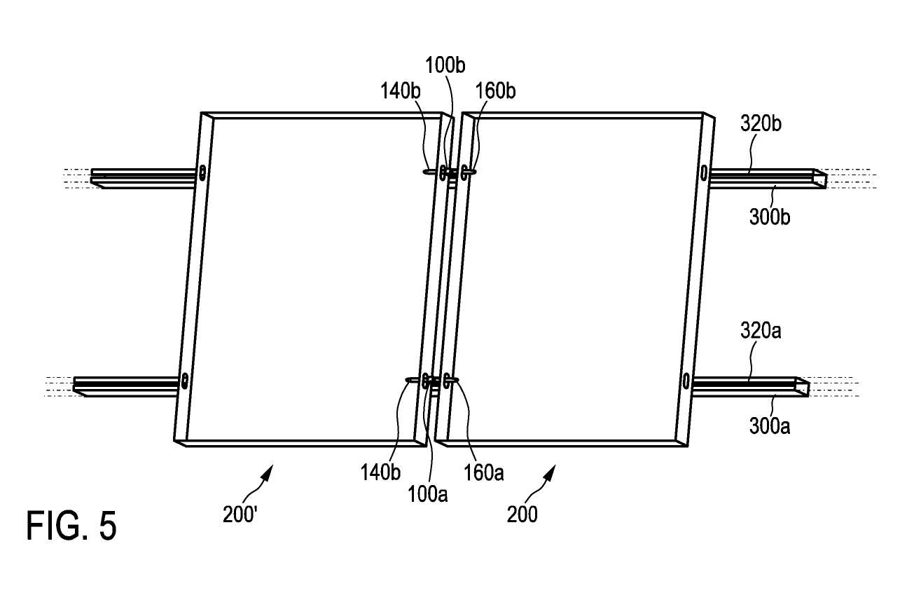

FIG. 5 illustrates an arrangement with two frames according to the fourth aspect of the invention;

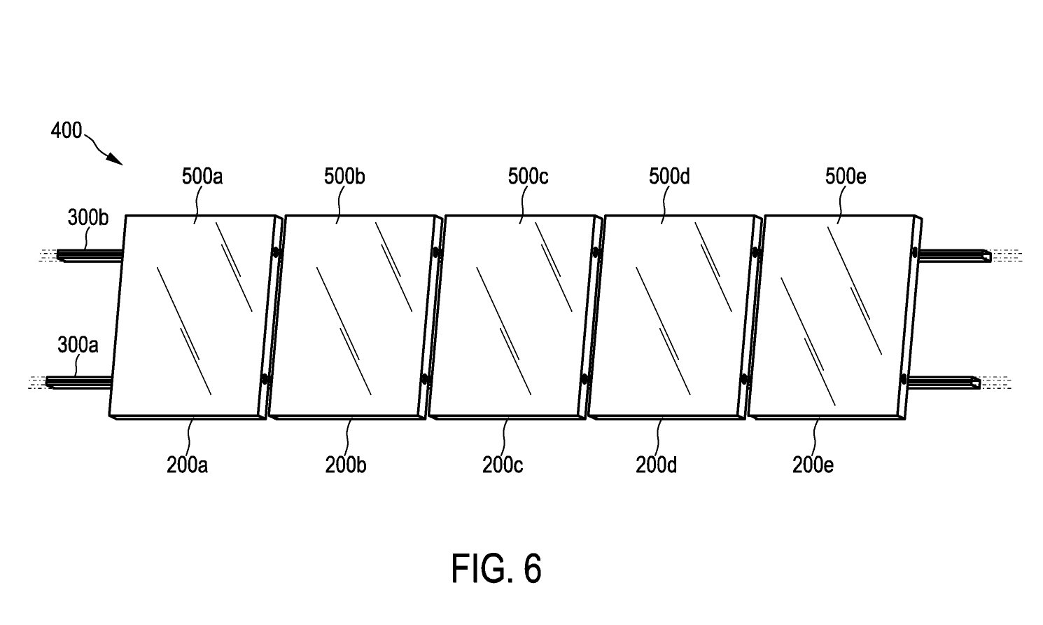

FIG. 6 illustrates a module field with photovoltaic modules according to the fifth aspect of the invention.

FIG. 2a illustrates a connection slider 100 according to the second aspect of the invention. The connection slider 100 includes an elongated cuboid main element 120.

Proximal to the first longitudinal end 130 of the main element, two mandrels 140, 160 are arranged which protrude from surfaces 122 and 124 of the main element 120 that are oriented in opposite directions. In the instant embodiment, the mandrels are arranged along a straight line.

At a longitudinal end 135 of the main element 120, a transversal element 180 is arranged wherein the longitudinal end 135 is arranged opposite to the first longitudinal end 130. The transversal element 180 includes two wedge shaped legs 190, 195 which are arranged at surfaces 126 and 128 of the main element 120 that are oriented in opposite directions. Thus the transversal element 180 forms an opposite profile through which a form locking connection with the profile of a profile rail (not illustrated) can be produced.

The main element 120 and the transversal element 180 viewed together have approximately T-shape. Thus the transversal bar of the T is the transversal element 180. At present it is arranged perpendicular to the straight line which includes the two mandrels 140, 160.

The two mandrels 140, 160 are respectively tapered towards their ends protruding from the main element. This facilitates inserting the mandrels 140, 160 in suitable recesses or frames which shall be attached through the connection slider 100. The taper, however, is not necessarily required for this purpose.

FIG. 2b illustrates a connection slider 100′ which differs from the connection slider 100 in FIG. 2a only in that a respective riffled contact portion 145′, 165′ is arranged on its mandrels 140′, 160′ adjacent to the main element 120′. The riffled contact portions 145′, 165′ are used for establishing an electrical connection between the connection slider 100′ and adjacent frames. The riffling increases the contact pressure in the inserted position of the respective mandrel in a punctiform manner, for a precise fabrication of the contact portion with reference to an inner dimension of the recited recess of the frame. A typically provided oxide layer can thus be broken through better which improves the conductivity of the electrical contact between frame and connection slider.

The connection slider is preferably completely made from electrically conductive material. The connection slider in inserted position also establishes a connection to the profile rail with its transversal element so that the connection slider, when a grounding of the profile rail is provided, also facilitates grounding the frames without additional measures.

FIG. 3 illustrates a frame 200 according to the third aspect of the invention. The frame 200 is rectangular and assembled form four frame elements 220, 222, 224 and 240. Two respective recesses are arranged on two outsides 225 and 245 of the frame elements 220 and 240, wherein the outsides 225 and 245 are oriented in different directions. At the frame element 220, recesses 230 and 235 are configured. By the same token, the frame element 240 respectively includes two recesses 250, 255. The recesses are configured for receiving a respective mandrel of a connection slider according to the second aspect of the invention.

The recesses 230, 235, 250, 255 are provided as identical slotted holes in the instant embodiment.

This facilitates assembly and also facilitates more tolerance relative to thermally induced length changes.

The recesses 230, 235, 250, 255 have dimensions which facilitate receiving a respective mandrel of a connection slider 100 from FIG. 2.

For simplicity reasons, the frame 200 is illustrated in FIG. 3 without photovoltaic module or without collector module. Thus the frame can be provided with a photovoltaic module or a collector module. Thus it suffices to insert the photovoltaic module or the collector module into the frame and attach it in a suitable manner.

According to the description of the connection slider 100 and of the frame 200, a method is subsequently described with reference to FIGS. 4a through 4h for mounting two frames on a profile rail 300 using the connection slider 100.

FIG. 4a illustrates the starting situation of the method. The profile rail 300 has a longitudinal groove 320 and an inner profile 340. The longitudinal groove 320 forms an opening in the profile rail 300 through which the connection slider 100 is insertable. The frame 200 lies on the profile rail 300 and contacts it, wherein for clarity reasons only a to portion of the first frame element 220 of the frame 200 is illustrated. The illustrated portion of the first frame element 220 has a slotted hole 235 already described in FIG. 3.

The connection slider 100 is not yet connected with the profile rail 300 in the method step of FIG. 4a.

Transitioning to the method step illustrated in FIG. 4b, the connection slider 100 is inserted with its transversal element 180 and a portion of its main element 120 into the longitudinal groove 320 of the profile rail 300.

Subsequently, the connection slider 100 is rotated by approximately 90°. An intermediary position with a not yet completely rotated connection slider 100 is illustrated in FIG. 4c.

FIG. 4d illustrates the condition after the complete rotation of the connection slider 100. The two mandrels 140, 160 are now parallel to the longitudinal groove 320 of the profile rail 300.

Subsequently, the connection slider 100 is moved along the longitudinal groove 320 of the profile rail 300 in a direction of the first frame element 220. FIG. 4e illustrated an intermediary condition during insertion. The mandrel 160 is only partially inserted into the slotted hole 235 in this intermediary condition.

After inserting the mandrel 160 until the surface 122 contacts at the frame element 220, the condition illustrated in FIG. 4f is reached.

In the same manner, a second connection slider 100′ is inserted into the slotted hole 235 of the frame element 220 on a second profile rail 300′ that is parallel to the first profile rail. This is not illustrated in the context of the instant method description. Reference is made to the illustration of the arrangement according to FIG. 5 described infra.

After inserting the second connection slider 100′ between the connection sliders 100 and the profile rail 300 and also between the first frame element 220 and the connection slider 100, a respective form locking connection is established, the first frame 200 in this method step is secured on the profile rail 300 against movement perpendicular to the longitudinal direction of the profile rail 300, besides the clearance which is provided by the slotted holes 230 and 235.

Subsequently as illustrated in FIG. 4g, a second frame 200′ is applied to the profile rail 300. The second frame 200′ is identical with the first frame 200. Therefore, subsequently the same reference numerals are used for like components of the frame 200′ with reference to the frame 200, wherein however an apostrophe designates their association with the frame 200′.

FIG. 4g again only illustrates a portion of a second frame element 240′ with a slotted hole 255′. The second frame 200′ is thus applied to the profile rail 300, so that its slotted hole 255′ is arranged approximately above the longitudinal groove 320 of the profile rail 300 and thus also approximately on an imaginary extension of the mandrel 140 of the connection slider 100.

Subsequently, the second frame 200′ is moved in a direction of the connection slider 100 so that the mandrel 140 is inserted into the slotted hole 255′. The final condition of this method step is illustrated in FIG. 4h, wherein the second frame element 240′ of the frame 200′ is in a surface contact with its outside with the surface 124 of the connection slider 100. Thus also the second frame 200′ is attached at the profile rail 300 through the connection slider 100. The two frames support the connection slider 100 through a suitable elevation position of their slotted holes at the frame simultaneously in form locking connection with the profile of the profile rail. This way also a lateral movement of the frames along the profile rail is made more difficult or prevented besides controlled force impact during assembly.

It is appreciated that the described sequence for the method is not mandatory. The connection sliders can for example also be inserted first into the profile rail and then inserted into the frames when the frames are already on the profile rails. Also for this variant, the frames are pushed together step by step always when a new pair of connection sliders was inserted into the two profile rails. Certainly various other variants of the assembly step sequence are feasible which are selected by a person skilled in the art for a respective assembly situation according to the preceding description.

The arrangement of the two frames 200 and 200′ on two profile rails 300 and 300a is illustrated in FIG. 5. As customary, the profile rails 300 and 300a are arranged parallel with one another and parallel to the ground (not illustrated), however, with different distance from the ground.

In respective longitudinal grooves 320a, 320b, two connection sliders 100a, 100b are inserted, whose mandrels respectively 140a, b and 160a, b are inserted in respective recesses of the first frame 200a and the second frame 200b. Thus the two frames 200a, 200b are supported on the profile rails.

It is apparent that additional frames can be mounted in both directions along the profile rails 300a and 300b. No additional bolted connection is required for this purpose.

Only at an end of a row of frames that are adjacent to one another on two profile rails that are arranged parallel to one another, a bolted end support (not illustrated) and an expansion joint (both not illustrated) can be mounted. Thus the bolted connection is used for securing against undesirable lateral sliding under strong force impact (storm or similar) and can also be provided with a theft safety. The expansion joint is used for compensating thermally induced length changes.

When photovoltaic modules are attached on the profile rails in the frames before or after mounting the frames this yields a module field. An exemplary detail from a module field of this type is illustrated in FIG. 6. The module field 400 includes two profile rails 300a, 300b on which frames 200a, 200b, 200c, 200d, 200e are mounted. In the frames 200a, 200b, 200c, 200d, 200e, photovoltaic modules 500a, 500b, 500c, 500d, 500e are attached.

Typical module fields are not only made from a concatenation of frames with respective photovoltaic modules or collector modules but also from an arrangement of plural pairs of profile rails with respective frames one behind another. Thus, surfaces of any size can be used for power generation or heating up a fluid.

In the module field of FIG. 6, 22 respective modules are switched together in order to facilitate a good adaptation of the power of the solar modules to customary power invertors. Depending on the correct power data of the photovoltaic modules and the invertors, however, also another number of interconnections can be suitable.

The module field 400 according to the fifth aspect of the invention does not only have the advantage of simple mounting with little materials usage, but also facilitates a simple exchange of the frames 200a, 200b, 200c, 200d, 200e or the connection sliders arranged between these frames. For this purpose, only an end support that is respectively arranged after a row of frames (not illustrated) which is typically bolted down has to be disengaged in order to be able to move the frames and the associated connection sliders of the row. When the element to be retrieved is exposed, it can be retrieved in a simple manner and replaced. Subsequently, the frames are pushed together again. Thus, it is not necessary anymore to disengage a plurality of bolted connections when replacing an element becomes necessary.

1. A connection slider for attaching two adjacent frames of photovoltaic modules or collector modules on a profile rail, the connection slider comprising:
a main element;
two mandrels which extend from two surfaces of the main element oriented in opposite directions, wherein one respective mandrel is insertable into one of the adjacent frames; and
a transversal element protruding from the main element, wherein the transversal element has an opposite profile adapted to a profile of the profile rail for providing a form locking connection with the profile rail.

2. The connection slider according to claim 1, wherein the transversal element protrudes from the main element in two directions that are opposite to one another and oriented transversal to a longitudinal direction of the mandrels.

3. The connection slider according to claim 1, wherein a longitudinal orientation of the main element is transversal to a longitudinal orientation of the mandrels.

4. The connection slider according to claim 1, wherein the transversal element protrudes from the main element in two directions that are opposite to one another and which are oriented transversal to a longitudinal direction of the main element.

5. The connection slider according to claim 1,
wherein the main element and the transversal element viewed together approximately have a T-shape,
wherein the transversal element is a transversal beam of the T.

6. The connection slider according to claim 1, wherein the transversal element includes two wedge shaped free legs.

7. The connection slider according to claim 6, wherein the wedge shaped legs taper in longitudinal direction of the main element viewed from a longitudinal end of the main element.

8. The connection slider according to claim 1, wherein the connection slider is configured integral in one piece.

9. The connection slider according to claim 1, wherein the transversal piece is configured so that it is insertable into an opening of the profile of the profile rail and establishes a form locking connection with the profile of the profile rail through subsequent rotation by approximately 90°.

10. The connection slider according to claim 1, wherein the mandrels in a longitudinal sectional view proximal to the main element respectively include an electrically conductive contact portion whose surface is riffled.

11. A frame for receiving one or plural photovoltaic modules or collector modules, comprising:
two frame elements on outsides of the frame oriented in opposite directions,
wherein the frames respectively include at least two recesses for receiving a respective mandrel of a connection slider according to claim 1.

12. The frame according to claim 11, wherein the recesses are configured as slotted holes.

13. An arrangement, comprising:
at least two profile rails arranged parallel to one another;
at least two frames arranged parallel to one another according to claim 11 and resting on the profile rails,
wherein the frames are arranged on the profile rails, so that, two respective recesses in the frame elements are arranged opposite from and oriented towards one another at a level of the profile rails,
wherein a respective connection slider comprises:
a main element;
two mandrels which extend from two surfaces of the main element oriented in opposite directions, wherein one respective mandrel is insertable into one of the adjacent frames; and
a transversal element protruding from the main element, wherein the transversal element has an opposite profile adapted to a profile of the profile rail for providing a form locking connection with the profile rail, and is arranged between the two recesses oriented opposite to one another,
wherein mandrels of the connection slider are inserted into the recesses,
wherein the transversal elements of the connection slider are in form locking connection with the respective profile rail, and
wherein a longitudinal orientation of the mandrels is parallel to a longitudinal orientation of the profile rails.

14. The arrangement according to claim 13, wherein the profile rails are arranged at different levels above ground.

15. The arrangement according to claim 13,
wherein between seven and fifteen frames are arranged in a row adjacent to one another,
wherein two respective adjacent frames are only offset from one another through the connection sliders and a bolted end support and an expansion joint are arranged at least at one end of the row.

16. A module field with photovoltaic modules or collector modules which are mounted through at least one arrangement according to claim 13.

17. The module field according to claim 16 with photovoltaic modules,
wherein the photovoltaic modules of eighteen to twenty six frames are respectively electrically connected with one another, and
some of the frames are mounted through at least one arrangement according to claim 9.

18. A use of connection sliders according to claim 1 for attaching at least two frames, wherein each frame is for receiving one or plural photovoltaic modules or collector modules, and comprises:
two frame elements on outsides of the frame oriented in opposite directions,
wherein the frames respectively include at least two recesses for receiving a respective mandrel of the connection slider, and
at least at two profile rails arranged parallel with one another.

19. A method comprising:
inserting a first connection slider into a longitudinal groove of a first profile rail;
providing a form locking connection of the first connection slider with the first profile rail;
moving the first connection slider along a longitudinal groove of the first profile rail towards a first frame for inserting a first mandrel of the first connection slider into a recess of the first frame for providing a form locking connection between the first frame and the first connection slider;
inserting a second connection slider into a longitudinal groove of a second profile rail;
establishing a form locking connection of the second connection slider with the second profile rail;
moving the second connection slider along a longitudinal groove of the second profile rail towards the first frame for inserting a first mandrel of the second connection slider into a recess of the first frame for providing a form locking connection between the first frame and the second connection slider;
arranging a second frame on the profile rails adjacent to the first frame, so that two respective recesses are arranged opposite to one another approximately at identical elevations in the adjacently arranged frames; and
moving the second frame for inserting a respective second mandrel of the connection sliders into the respective recess of the second frame.

20. The method according to claim 19,
wherein a total of seven to fifteen frames is mounted adjacent to one another,
wherein the frames are only offset from one another through the connection sliders, and
wherein a bolted end support and an expansion joint are mounted thereafter.

21. The method according to claim 20, wherein an electrical connection of photovoltaic modules received in the frames is provided after mounting a total of eighteen to twenty six frames with expansion joints arranged there between.
